(19) United States
(12) Patent Application Publication
(10) Pub. No.: US 2025/0287794 A1
(43) Pub. Date: Sep. 11, 2025

(54) DISPLAY SUBSTRATE AND DISPLAY DEVICE

(71) Applicants: Chengdu BOE Optoelectronics Technology Co., Ltd., Chengdu, Sichuan (CN); BOE Technology Group Co., Ltd., Beijing (CN)

(72) Inventors: Yi QU, Beijing (CN); Peng XU, Beijing (CN); Yang ZHOU, Beijing (CN); Lu BAI, Beijing (CN); Zhiwen CHU, Beijing (CN); Song LIU, Beijing (CN); Xinxin WANG, Beijing (CN)

(21) Appl. No.: 18/861,883

(22) PCT Filed: Jan. 8, 2024
(86) PCT No.: PCT/CN2024/071130

§ 371 Date: Oct. 31, 2024

(30) Foreign Application Priority Data
Jan. 13, 2023 (CN) 202310072350.8

(51) Int. Cl. H10K 59/131

(52) U.S. Cl. CPC H10K 59/131

(57) ABSTRACT

A display substrate, includes: a base substrate, a plurality of sub-pixels, a plurality of data lines, a plurality of first contact pads, a plurality of second contact pads, and an inorganic film. The base substrate includes a display region and a peripheral region surrounding the display region. The peripheral region includes at least one driver chip disposing region. The plurality of first contact pads are located in the at least one driver chip disposing region and connected to the plurality of data lines. The plurality of second contact pads are located in the at least one driver chip disposing region and located on the side of the plurality of first contact pads away from the display region, and the plurality of first contact pads and the plurality of second contact pads are configured to be bonded to a driving chip.

### CROSS-REFERENCE TO RELATED APPLICATIONS

The present application is a U.S. National Phase Entry of International Application PCT/CN2024/071130 having an international filing date of Jan. 8, 2024, which claims priority to Chinese Patent Application No. 202310072350.8 filed to the CNIPA on Jan. 13, 2023 and entitled “DISPLAY SUBSTRATE AND DISPLAY DEVICE”, and the contents disclosed in the above-mentioned applications are hereby incorporated as a part of this application.

### TECHNICAL FIELD

The present disclosure relates to, but is not limited to, the field of display technologies, in particular to a display substrate and a display apparatus.

### BACKGROUND

Organic Light Emitting Diodes (OLED's) and Quantum-dot Light Emitting Diodes (QLED's) are active light emitting display devices and have advantages of self-illumination, a wide viewing angle, a high contrast ratio, low power consumption, an extremely high reaction speed, lightness and thinness, flexibility, and low cost, etc. A full display with camera technology is a novel technology proposed for increasing a screen-to-body ratio of a display apparatus.

### SUMMARY

The following is a summary of subject matters described herein in detail. This summary is not intended to limit the protection scope of claims.

Embodiments of the present disclosure provide a display substrate and a display apparatus.

In one aspect, in an embodiment, a display substrate is provided, which includes a base substrate, a plurality of sub-pixels, a plurality of data lines, a plurality of first contact pads, a plurality of second contact pads, and an inorganic film. The base substrate includes a display region and a peripheral region surrounding the display region. The peripheral region includes at least one driver chip disposing region. The plurality of sub-pixels are located in the display region, the plurality of data lines are located in the display region and the peripheral region, and the plurality of sub-pixels and the plurality of data lines are electrically connected. The plurality of first contact pads are located in the at least one driver chip disposing region, and are connected with the plurality of data lines. The plurality of second contact pads are located in the at least one driver chip disposing region and on a side of the plurality of first contact pads away from the display region, the plurality of first contact pads and the plurality of second contact pads are configured to bond to a driver chip. The inorganic film includes at least one inorganic groove. The at least one inorganic groove is located on at least one side of the plurality of first contact pads or the plurality of second contact pads.

In some exemplary implementations, the at least one inorganic groove includes a first inorganic groove, and an orthographic projection of the first inorganic groove on the base substrate at least partially surrounds orthographic projections of the plurality of first contact pads or the plurality of second contact pads on the base substrate.

In some exemplary implementations, an orthographic projection of the first inorganic groove on the base substrate surrounds orthographic projections of the plurality of first contact pads and the plurality of second contact pads on the base substrate.

In some exemplary implementations, an edge of the first inorganic groove is serrated.

In some exemplary implementations, the at least one driver chip disposing region is located in a first signal access region of the peripheral region; a total thickness of the inorganic film in the at least one driver chip disposing region is less than a total thickness of the inorganic film in a region other than the driver chip disposing region in the first signal access region.

In some exemplary implementations, the at least one driver chip disposing region further includes a plurality of signal leads. the at least one inorganic groove includes a plurality of second inorganic grooves, at least part of the plurality of second inorganic grooves is located in the at least one driver chip disposing region, and orthographic projections of the plurality of second inorganic grooves on the base substrate are not overlapped with orthographic projections of the plurality of first contact pads, the plurality of second contact pads, and the plurality of signal leads on the base substrate.

In some exemplary implementations, the plurality of second inorganic grooves extend in a same direction.

In some exemplary implementations, the at least one inorganic groove includes at least one third inorganic groove at least partially surrounding the plurality of first contact pads and the plurality of second contact pads, the at least one third inorganic groove is an annular groove.

In some exemplary implementations, an orthographic projection of the at least one third inorganic groove on the base substrate is not overlapped with the orthographic projections of the plurality of first contact pads and the plurality of second contact pads on the base substrate.

In some exemplary implementations, the plurality of first contact pads include a plurality of groups of first contact pads, each group of first contact pads is arranged along a first direction, the plurality of groups of first contact pads are arranged along a second direction, the first direction intersects with the second direction; the plurality of second contact pads include at least one group of second contact pads, each group of second contact pads is arranged along the first direction.

In some exemplary implementations, the display substrate further includes a plurality of third contact pads located in the at least one driver chip disposing region; the plurality of third contact pads are located between the plurality of first contact pads and the plurality of second contact pads in the second direction. The plurality of third contact pads include at least one group of third contact pads, each group of third contact pads is arranged along the first direction.

In some exemplary implementations, the display substrate further includes a plurality of dummy contact pads located in the at least one driver chip disposing region; the plurality of dummy contact pads include at least one group of dummy contact pads, each group of dummy contact pads is arranged along the second direction, and each group of dummy contact pads is located on at least one side of the plurality of third contact pads in the first direction.

In some exemplary implementations, the display substrate further includes a plurality of signal leads located in the at least one driver chip disposing region; the plurality of signal leads are electrically connected with the plurality of third contact pads, respectively, and are configured to transmit a signal in a test phase.

In some exemplary implementations, in a direction perpendicular to the display substrate, the display region includes: a base substrate and a circuit structure layer disposed on the base substrate, the circuit structure layer includes a first semiconductor layer, a first insulation layer, a first gate metal layer, a second insulation layer, a second gate metal layer, a third insulation layer, a second semiconductor layer, a fourth insulation layer, a third gate metal layer, a fifth insulation layer, a first source-drain metal layer, a sixth insulation layer, a second source-drain metal layer and a seventh insulation layer disposed on the base substrate. The inorganic film includes a first insulation layer, a second insulation layer, a third insulation layer, a fourth insulation layer, and a fifth insulation layer disposed on the base substrate sequentially; the at least one inorganic groove is configured to be formed by reducing a thickness of at least one of the first insulation layer to the fifth insulation layer.

In some exemplary implementations, at least one contact pad of the plurality of first contact pads and the plurality of second contact pads includes at least two conductive blocks electrically connected; the at least two conductive blocks are located in at least two metal layers of the first gate metal layer, the second gate metal layer, the third gate metal layer, the first source-drain metal layer, and the second source-drain metal layer.

In another aspect, an embodiment of the present disclosure provides a display apparatus, which includes the aforementioned display substrate.

Other aspects of the present disclosure may be comprehended after the drawings and the detailed descriptions are read and understood.

### BRIEF DESCRIPTION OF DRAWINGS

Accompanying drawings are used for providing further understanding of technical solutions of the present disclosure, constitute a portion of the specification, and are used for explaining the technical solutions of the present disclosure together with embodiments of the present disclosure, but do not constitute limitations on the technical solutions of the present disclosure. Shapes and sizes of one or more components in the drawings do not reflect actual scales, but are only intended to schematically describe contents of the present disclosure.

FIG. 1 is a schematic diagram of a structure of a display apparatus.

FIG. 2 is a schematic plan view of a display substrate.

FIG. 3 illustrates schematically a partial cross-sectional view of a structure of a display region of a display substrate.

FIG. 4 is a schematic diagram of a first bezel region of a display substrate.

FIG. 5 is a schematic diagram of a part of a first signal access region of a display substrate according to at least one embodiment of the present disclosure.

FIG. 6 is a schematic diagram of a partition of a first signal access region of a display substrate according to at least one embodiment of the present disclosure.

FIG. 7 is a partially enlarged schematic diagram of a region SS2 in FIG. 6.

FIG. 8 illustrates schematically a cross-sectional view of a part taken along a direction Q-Q′ in FIG. 7.

FIG. 9 illustrates schematically a cross-sectional view of a part taken along a direction P-P′ in FIG. 6.

FIG. 10 is another schematic diagram of a part of a first signal access region of a display substrate according to at least one embodiment of the present disclosure.

FIG. 11 is a partially enlarged schematic diagram of a region SS3 in FIG. 10.

FIG. 12 is another schematic diagram of a part of a first signal access region of a display substrate according to at least one embodiment of the present disclosure.

FIG. 13 is another schematic diagram of a part of a first signal access region of a display substrate according to at least one embodiment of the present disclosure.

### DETAILED DESCRIPTION

The embodiments of the present disclosure will be described below with reference to the drawings in detail. Implementations may be implemented in a plurality of different forms. Those of ordinary skills in the art may easily understand such a fact that implementations and contents may be transformed into other forms without departing from the purpose and scope of the present disclosure. Therefore, the present disclosure should not be explained as being limited to the contents recorded in the following implementations only. The embodiments and features in the embodiments of the present disclosure may be randomly combined with each other if there is no conflict.

In the drawings, a size of one or more constituent elements, a thickness of a layer, or a region is sometimes exaggerated for clarity. Therefore, one implementation of the present disclosure is not necessarily limited to the size, and a shape and a size of one or more components in the drawings do not reflect an actual scale. In addition, the accompanying drawings schematically illustrate ideal examples, and an implementation of the present disclosure is not limited to shapes, numerical values, or the like shown in the drawings.

Ordinal numerals “first”, “second”, “third”, etc., in the specification are set not to form limits in numbers but only to avoid confusion between composition elements. In the present disclosure, “plurality” represents two or more than two.

In the specification, for convenience, expressions “central”, “above”, “below”, “front”, “back”, “vertical”, “horizontal”, “top”, “bottom”, “inside”, “outside”, etc., indicating directional or positional relationships are used to illustrate positional relationships between the composition elements with reference to the accompanying drawings, not to indicate or imply that involved devices or elements are required to have specific orientations and be structured and operated with the specific orientations but only to easily and simply describe the present specification, and thus should not be understood as limitations on the present disclosure. The positional relationships between the constituent elements are changed as appropriate according to directions of the constituent elements described. Therefore, appropriate replacements based on situations are allowed, which is not limited to the expressions in the specification.

In the specification, unless otherwise specified and defined, terms “mounting”, “mutual connection”, and “connection” should be understood in a broad sense. For example, it may be a fixed connection, a detachable connection, or an integral connection; it may be a mechanical connection or a connection; it may be a direct connection, an indirect connection through a middleware, or an internal communication inside two elements. Those of ordinary skills in the art may understand meanings of the aforementioned terms in the present disclosure according to situations.

In the specification, an “electrical connection” includes a case that constituent elements are connected together through an element with a certain electrical action. The “element with a certain electrical effect” is not particularly limited as long as electrical signals between the connected constituent elements may be transmitted. Examples of the “element having some electrical function” not only include an electrode and a wiring, but also include a switching element such as a transistor, a resistor, an inductor, a capacitor, another element with multiple functions, etc.

In the specification, a transistor refers to an element which at least includes three terminals, i.e., a gate electrode, a drain electrode, and a source electrode. The transistor has a channel region between the drain electrode (drain electrode terminal, drain electrode region, or drain electrode) and the source electrode (source electrode terminal, source electrode region, or source electrode), and a current can flow through the drain electrode, the channel region, and the source electrode. In the specification, the channel region refers to a region through which a current mainly flows.

In the specification, a first electrode may be a drain and a second electrode may be a source, or, a first electrode may be a source and a second electrode may be a drain. In a case that transistors with opposite polarities are used, or in a case that a direction of a current is changed during operation of a circuit, or the like, functions of the “source electrode” and the “drain electrode” are sometimes interchangeable. Therefore, the “source electrode” and the “drain electrode” are interchangeable in the specification. In addition, the gate may also be referred to as a control electrode.

In the specification, “parallel” refers to a state in which an angle formed by two straight lines is above −10° and below 10°, and thus may include a state in which the angle is above −5° and below 5°. In addition, “perpendicular” refers to a state in which an angle formed by two straight lines is above 80° and below 100°, and thus may include a state in which the angle is above 85° and below 95°.

In this specification, a circle, oval, triangle, rectangle, trapezoid, pentagon or hexagon, etc. is not strictly speaking, but may be an approximate circle, oval, triangle, rectangle, trapezoid, pentagon or hexagon, etc. Some small deformations due to tolerances may exist, for example, lead angles, curved edges and deformations thereof may exist.

In the present disclosure, “about” and “substantially” refer to that a boundary is not defined strictly and a case within a range of process and measurement errors is allowed. In the present disclosure, “substantially the same” refers to a case where numerical values differ by less than 10%.

In the present disclosure, “A extends along a B direction” means that A may include a main body portion and a secondary portion connected with the main body portion, the main body portion is a line, a line segment, or a strip-shaped body, the main body portion extends along the B direction, and a length of the main body portion extending along the B direction is greater than a length of the secondary portion extending along another direction. “A extends along the B direction” in the present disclosure means “the main portion of A extends along the B direction”. In the present disclosure, a width of A may refer to a length of A in a direction perpendicular to an extending direction in a plane parallel to the display substrate. A depth of A may refer to a dimension of A in a direction perpendicular to a plane on which the display substrate is located.

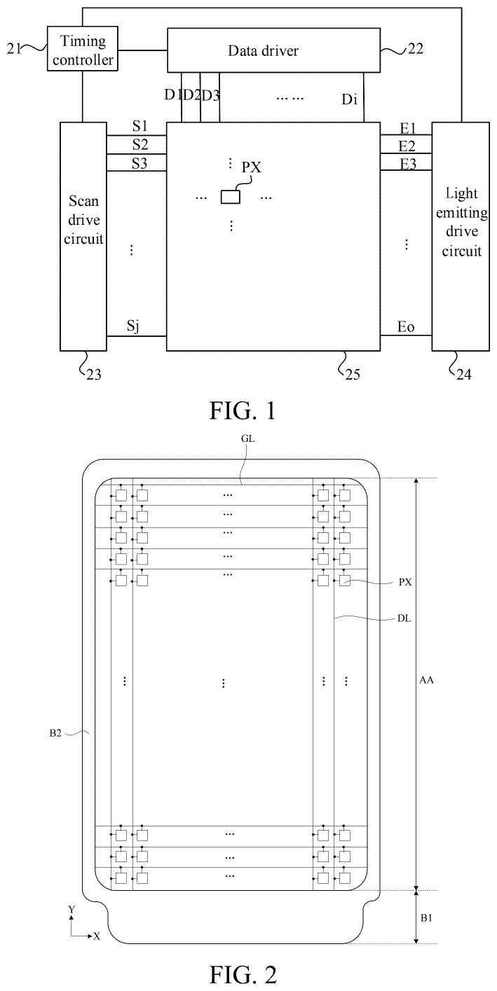

FIG. 1 is a schematic diagram of a structure of a display apparatus. In some examples, as shown in FIG. 1, the display apparatus may include a timing controller 21, a data driver 22, a scan drive circuit 23, a light emitting driver 24, and a sub-pixel array 25. In some examples, the sub-pixel array 25 may include a plurality of sub-pixels PX arranged regularly. The scan drive circuit 23 may be configured to provide a scan signal to a sub-pixel PX along a scan line. The data driver 22 may be configured to provide a data voltage to a sub-pixel PX along a data line. The light emitting drive circuit 24 may be configured to provide a light emitting control signal to a sub-pixel PX along a light emitting control line. The timing controller 21 may be configured to control the scan drive circuit 23, the light emitting drive circuit 24 and the data driver 22.

In some examples, the timing controller 21 may provide the data driver 22 with a gray-scale value and a control signal suitable for a specification of the data driver 22, the timing controller 21 may provide the scan drive circuit 23 with a scan clock signal, a scan start signal, etc., suitable for a specification of the scan drive circuit 23, and the timing controller 21 may provide the light emitting drive circuit 24 with a light emitting clock signal, a light emitting start signal, etc., suitable for a specification of the light emitting drive circuit 24. The data driver 22 may generate a data voltage to be provided to data lines D1 to Di, using the gray-scale value and the control signal received from the timing controller 21. For example, the data driver 22 may sample the gray-scale value using the clock signal and apply a data voltage corresponding to the gray-scale value to the data lines D1 to Di using a sub-pixel row as a unit. The scan circuit 23 may receive the scan clock signal, the scan start signal, etc., from the timing controller 21 to generate a scan signal to be provided to scan lines S1 to Sj. For example, the scan drive circuit 23 may sequentially provide scan signals with on-level pulses to scan lines. In some examples, the scan drive circuit 23 may include a shift register and sequentially transmit the scan start signal provided in form of an on-level pulse to a next-stage circuit to generate the scan signal under control of the scan clock signal. The light emitting drive circuit 24 may receive the light emitting clock signal, the light emitting start signal, etc., from the timing controller 21 to generate a light emitting control signal to be provided to light emitting control lines E1 to Eo. For example, the light emitting drive circuit 24 may provide sequentially light emitting control signals with an off-level pulse to the light emitting control lines. The light emitting drive circuit 24 may include a shift register, and generate a light emitting control signal by sequentially transmitting a light emitting start signal provided in a form of an off-level pulse to a next-stage circuit under control of the clock signal. Herein, i, j, and o are all natural numbers.

In some examples, the display apparatus may include a display substrate. The sub-pixel array may be disposed in a display region of the display substrate. The scan drive circuit and the light emitting drive circuit may be directly provided on the display substrate. For example, the scan drive circuit may be provided on a left bezel of the display substrate, and the light emitting drive circuit may be provided on a right bezel of the display substrate. Or, each of the left bezel and the right bezel of the display substrate may be provided with a scan drive circuit and a light emitting driving circuit. In some examples, the scan drive circuit and the light emitting drive circuit may be formed together with the sub-pixels in a process of forming the sub-pixels.

In some examples, the data driver may be disposed on an independent chip or printed circuit board to be connected to the sub-pixel through the signal access pin on the display substrate. For example, the data driver may be formed and disposed at a lower bezel of the display substrate using a chip on glass, a chip on plastics, a chip on film, etc., to be connected to the signal access pin. The timing controller may be arranged separately from or integrally with the data driver. However, the present embodiment is not limited thereto. In some examples, the data driver may be directly disposed on the display substrate.

FIG. 2 is a schematic plan view of a display substrate. In some examples, as shown in FIG. 2, the display substrate may include a display region AA, and a peripheral region surrounding the display region AA. The peripheral region may include a first bezel region B1 located on one side of the display region AA, and a second bezel region B2 located on other sides of the display region AA. The second bezel region B2 may be located, at least, on two sides of the first bezel region B1. The first bezel region B1 may be, for example, the lower bezel of the display substrate, and the bezel region B2 may include an upper bezel, a left bezel, and a right bezel of the display substrate. In some examples, the display region AA may be a planarization region including a plurality of sub-pixels PX that form a pixel array, and the plurality of sub-pixels PX are configured to display a dynamic picture or a static image. The display region may be referred to as an effective region. In some examples, the display substrate may be a flexible substrate. Accordingly, the display substrate may be deformable, for example, crimped, bent, folded, or curled.

In some examples, the second bezel region B2 may include a circuit region, a power supply line region, a crack dam region, and a cutting region which are sequentially disposed along a direction of the display region AA. The circuit region may be connected to the display region AA, and the circuit region may include, at least, a gate drive circuit (for example, the gate drive circuit includes a plurality of cascaded shift registers), and the plurality of shift registers may be electrically connected to a plurality of gate lines in the display region AA. The power supply line region is connected to the circuit region and may at least include a low-level power supply line. The low-level power supply line may extend along a direction parallel to an edge of the display region and is connected to a cathode in the display region AA. The crack dam region may be connected to the power supply line region and may at least include a plurality of cracks provided on a composite insulation layer. The cutting region may be connected to the crack dam region, and may at least include cutting grooves provided on the composite insulation layer. The cutting grooves are configured such that a cutting device cuts along the cutting grooves respectively after preparation of all films of the display substrate is completed.

In some examples, the first bezel region B1 and the second bezel region B2 may be provided with a first separating bank and a second separating bank, which may extend in a direction parallel to an edge of the display region to form a ring structure surrounding the display region AA, and the edge of the display region may be an edge of the display region close to the first bezel region or the second bezel region.

In some examples, as shown in FIG. 2, the display region AA may include, at least, a plurality of sub-pixels PX, a plurality of gate lines GL, and a plurality of data lines DL. The plurality of gate lines GL may extend along a first direction X, and the plurality of data lines DL may extend along a second direction Y. Orthographic projections of the plurality of gate lines GL on the base substrate intersect with orthographic projections of the plurality of data lines DL on the base substrate to form a plurality of sub-pixel regions, and one sub-pixel PX is provided in each of the sub-pixel regions. The plurality of data lines DL are electrically connected with the plurality of sub-pixels PX and the plurality of data lines DL may be configured to provide data signals to the plurality of sub-pixels PX. The plurality of data lines DL may extend to the bonding region B1. The plurality of gate lines GL are electrically connected with the plurality of sub-pixels PX and the plurality of gate lines GL may be configured to provide a gate control signal to the plurality of sub-pixels PX. In some examples, the gate control signals may include a scan signal and a light emitting control signal.

In some examples, as shown in FIG. 2, the first direction X may be an extending direction (row direction) of the gate lines GL in the display region AA, and the second direction Y may be an extending direction (column direction) of the data lines DL in the display region AA. The first direction X and the second direction Y may be perpendicular to each other.

In some examples, a pixel unit of the display region AA may include three sub-pixels which are a red sub-pixel, a green sub-pixel, and a blue sub-pixel respectively. However, the present embodiment is not limited thereto. In some examples, one pixel unit may include four sub-pixels, and the four sub-pixels are a red sub-pixel, a green sub-pixel, a blue sub-pixel, and a white sub-pixel respectively.

In some examples, a shape of a sub-pixel may be a rectangle, a rhombus, a pentagon, or a hexagon. When one pixel unit includes three sub-pixels, the three sub-pixels may be arranged in parallel in a horizontal direction, in parallel in a vertical direction, or in a delta-shaped arrangement. When one pixel unit includes four sub-pixels, the four sub-pixels may be arranged in parallel in a horizontal direction, in parallel in a vertical direction, or in a shape forming a square. However, the present embodiment is not limited thereto.

In some examples, one sub-pixel may include a pixel circuit and a light emitting element electrically connected with the pixel circuit. The pixel circuit may include a plurality of transistors and at least one capacitor. For example, the pixel circuit may have a 3TIC, 4TIC, 5TIC, 5T2C, 6TIC, 7TIC, or 8TIC structure. In the above-mentioned circuit structures, T refers to a thin film transistor, C refers to a capacitor, a number before T represents a quantity of thin film transistors in the circuit, and a number before C represents a quantity of capacitors in the circuit. In some examples, the plurality of transistors in the pixel circuit may be P-type transistors or may be N-type transistors. Usage of same type of transistors in the pixel circuit may simplify a process flow, reduce a process difficulty of the display substrate, and improve a yield of a product. In some other examples, the plurality of transistors in the pixel circuit may include a P-type transistor and an N-type transistor.

In some examples, low temperature poly silicon thin film transistors, or oxide thin film transistors, or both a low temperature poly silicon thin film transistor and an oxide thin film transistor may be used as the plurality of transistors in the pixel circuit. Low Temperature Poly Silicon (LTPS) is adopted for an active layer of a low temperature poly silicon thin film transistor and an oxide semiconductor (Oxide) is adopted for an active layer of an oxide thin film transistor. The low temperature poly silicon thin film transistor has advantages such as a high migration rate and fast charging, and the oxide thin film transistor has advantages such as a low leakage current. The low temperature poly silicon thin film transistor and the oxide thin film transistor are integrated on one display substrate, that is, an LTPS+Oxide (LTPO for short) display substrate, advantages of both the low temperature poly silicon thin film transistor and the oxide thin film transistor may be utilized, so that low-frequency drive can be achieved, power consumption can be reduced, and display quality can be improved.

In some examples, the light emitting element may be any of a Light Emitting Diode (LED), an Organic Light Emitting Diode (OLED), a Quantum dot Light Emitting Diode (QLED), a micro LED (including: mini-LED or micro-LED), and the like. For example, the light emitting element may be an OLED, and the light emitting element may emit red light, green light, blue light, or white light, etc. under driving of a pixel circuit corresponding to the light emitting element. A color of light emitted by the light emitting element may be determined as required. In some examples, the light emitting element may include an anode, a cathode, and an organic light emitting layer located between the anode and the cathode. The anode of the light emitting element may be electrically connected to a corresponding pixel circuit. However, the present embodiment is not limited thereto.

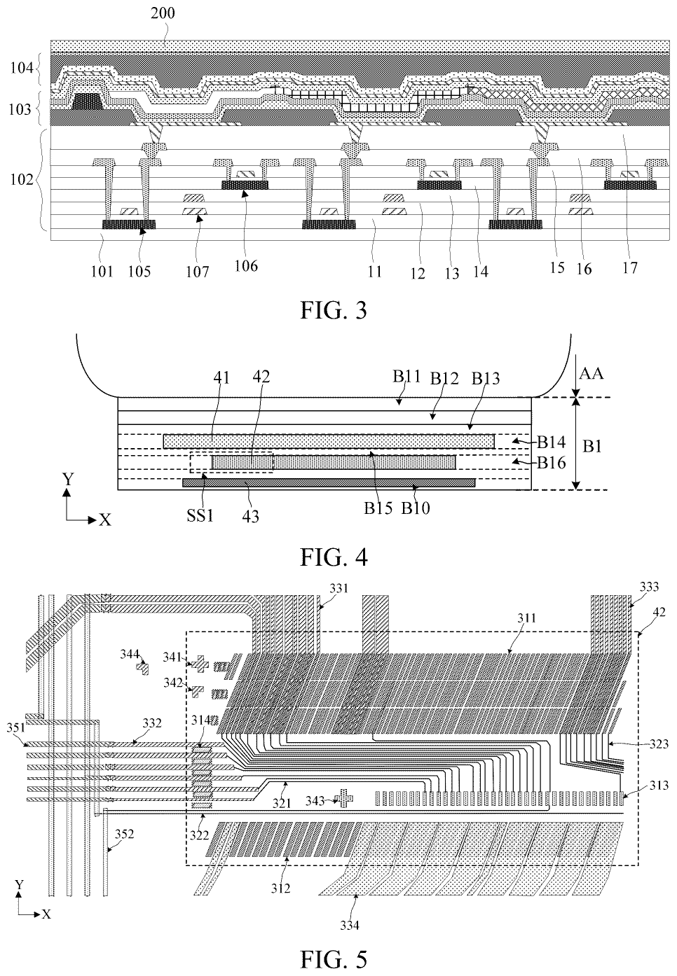

FIG. 3 illustrates schematically a partial cross-sectional view of a structure of a display region of a display substrate. FIG. 3 illustrates structures of three sub-pixels of the display substrate. In this example, an LTPO display substrate is described as an example. A plurality of transistors in a pixel circuit may be a low temperature poly silicon thin film transistor and an oxide thin film transistor.

In some example, as shown in FIG. 3, in a direction perpendicular to the display substrate, the display substrate may include: a base substrate 101, and a circuit structure layer 102, a light emitting structure layer 103, an encapsulation layer 104 and an encapsulation cover plate 200 that are sequentially disposed on the base substrate 101. In some possible implementations, the display substrate may include other films, such as a post spacer, a touch structure layer, which are not limited in the present disclosure herein.

In some examples, the base substrate 101 may be a rigid underlay substrate, such as a glass underlay substrate. Alternatively, the base substrate 101 may be a flexible underlay substrate, for example, made from a resin or other insulating materials. In addition, the substrate may be in a single-layer structure or a multilayer structure. When the base substrate is in a multilayer structure, an inorganic material such as silicon nitride, silicon oxide, and silicon oxynitride may be disposed between a plurality of layers as a single layer or multiple layers. However, the present embodiment is not limited thereto.

In some examples, a circuit structure layer 102 of each sub-pixel may include a plurality of transistors and a storage capacitor constituting a pixel circuit, and FIG. 3 is illustrated by taking each sub-pixel including one low temperature poly silicon thin film transistor (for example, a first transistor 105), one oxide thin film transistor (for example, a second transistor 106), and one storage capacitor (for example, a first capacitor 107) as an example. In some possible implementations, a circuit structure layer 102 of each sub-pixel may include: a first semiconductor layer (including, for example, an active layer of a low temperature poly silicon thin film transistor) disposed on the base substrate 101; a first insulation layer 11 (or referred to as a first gate insulation layer) covering the active layer; a first gate metal layer (including, for example, a gate electrode of the low temperature poly silicon thin film transistor, and a first capacitance electrode of the storage capacitor) provided on the first insulation layer 11; a second insulation layer 12 (or referred to as a second gate insulation layer) covering the first gate metal layer; a second gate metal layer (e.g., including a second capacitance electrode of the storage capacitor) provided on the second insulation layer 12; a third insulation layer 13 (or referred to as a third gate insulation layer) covering the second gate metal layer; a second semiconductor layer (including, for example, an active layer of the oxide thin film transistor) provided on the third insulation layer 13; a fourth insulation layer 14 (or referred to as a fourth gate insulation layer) covering the second semiconductor layer; a third gate metal layer (including, for example, a gate electrode of the oxide thin film transistor) provided on the fourth insulation layer 14; a fifth insulation layer 15 (or referred to as an interlayer insulation layer) covering the third gate metal layer; a first source-drain metal layer (including, for example, a source electrode and a drain electrode of the low temperature poly silicon thin film transistor and a source electrode and a drain electrode of the oxide thin film transistor) disposed on the fifth insulation layer 15; a sixth insulation layer 16 (or referred to as a first planarization layer) covering the aforementioned structure; a second source-drain metal layer (including, for example, a pixel connection electrode with an anode of a light emitting element) provided on the sixth insulation layer 16; and a seventh insulation layer 17 (or referred to as a second planarization layer) covering the second source-drain metal layer. The fifth insulation layer 15 is provided with a first pixel via and a second pixel via, wherein a fifth insulation layer 15, a fourth insulation layer 14, a third insulation layer 13, a second insulation layer 12, and a first insulation layer 11 within the first pixel via are removed to expose a surface of the first semiconductor layer, and the source electrode and the drain electrode of the low temperature poly silicon thin film transistor can be connected with the active layer through the first pixel via, respectively. A fifth insulation layer 15 and a fourth insulation layer 14 within the second pixel via may be removed to expose a surface of the second semiconductor layer, and the source electrode and the drain electrode of the oxide thin film transistor may be connected with the active layer through the second pixel via, respectively. The sixth insulation layer 16 may be provided with a third pixel via, and a pixel connection electrode located in the second source-drain metal layer may be electrically connected with a transistor of the pixel circuit through the third pixel via. The seventh insulation layer 17 may be provided with a fourth pixel via, and an anode of the light emitting element may be electrically connected with a pixel connection electrode located in the second source-drain metal layer through the fourth pixel via.

In some examples, as shown in FIG. 3, the first insulation layer 11 to the fifth insulation layer 15 may be made of an inorganic insulating material, and the sixth insulation layer 16 and the seventh insulation layer 17 may be made of an organic insulating material. However, the present embodiment is not limited thereto.

In some examples, as shown in FIG. 3, the light emitting structure layer 103 may include an anode layer, a pixel definition layer, an organic emitting layer, and a cathode. The anode layer may include the anode of the light emitting element, the anode may be disposed on the seventh insulation layer 17 and is connected with the pixel connection electrode through the fourth pixel via provided in the seventh insulation layer 17. The pixel definition layer is disposed on the anode layer and the seventh insulation layer 17. The pixel definition layer is provided with a pixel opening that exposes at least parts of surface of the anode. The organic light emitting layer is disposed, at least partially, within the pixel opening, and is connected with the anode. The cathode is disposed on the organic light emitting layer and is connected with the organic light emitting layer; and the organic light emitting layer emits light in a corresponding color under the driving of the anode and the cathode.

In some examples, as shown in FIG. 3, the encapsulation structure layer 104 may include a first encapsulation layer, a second encapsulation layer, and a third encapsulation layer that are stacked. The first encapsulation layer and the third encapsulation layer may be made of an inorganic material, and the second encapsulation layer may be made of an organic material. The second encapsulation layer is disposed between the first encapsulation layer and the third encapsulation layer, which may ensure that external water vapor cannot enter the light emitting structure layer 103.

In some examples, the organic light emitting layer may at least include a hole injection layer, a hole transport layer, a light emitting layer and a hole block layer which are stacked on the anode. In some examples, the hole injection layers of all sub-pixels may be a common layer connected together; the hole transport layers of all sub-pixels may be a common layer connected together; the light emitting layers of close to sub-pixels may be slightly overlapped or isolated; and the hole block layers may be a common layer connected together. However, the present embodiment is not limited thereto.

FIG. 4 is a schematic diagram of a first bezel region of a display substrate. FIG. 4 illustrates a schematic diagram of a display substrate before a bending process is performed. In some examples, as shown in FIG. 4, the first bezel region of the display substrate may include a first fan-out region B11, a bending region B12, a second fan-out region B13, a first circuit region B14, a third fan-out region B15, a first signal access region B16, and a second signal access region B10 disposed in sequence along a direction away from a display region AA. The first fan-out region B11 may be connected to the display region AA. The first fan-out region B11 may include, at least, a first power supply line and a second power supply line, and a plurality of data lines in the display region AA may extend to the first fan-out region B11 in a fan-out wiring manner. The first power supply line of the first fan-out region B11 may be configured to connect with a high-level power supply line of the display region AA, and the second power supply line may be configured to connect with a low-level power supply line of the bezel region. The bending region B12 is connected between the first fan-out region B11 and the second fan-out region B13, and may be configured such that a bonding region B1 is bent to the back of the display region AA. The first circuit region B14 may include at least one first circuit group 41. The first circuit group 41 may include a plurality of test circuits, which may be configured to electrically connect with a plurality of data lines to provide test data signals to a plurality of data lines of the display region AA during a test phase. The first circuit group 41 may further include an electrostatic discharge circuit. The first signal access region B16 may include at least one driver chip disposing region 42. In this example, one driver chip disposing region 42 is illustrated as an example. In some other examples, the first signal access region B16 may include a plurality of driver chip disposing regions sequentially disposed along the first direction X. Each driver chip disposing region 42 may include a plurality of conductive bumps (also referred to as contact pads) that may be configured to bond to at least one driver chip (Integrated Circuit, IC). The driver chip may be configured to generate a drive signal required for driving sub-pixels and to provide the drive signal to the data lines of the display region. For example, the drive signal may be a data signal that drives the sub-pixels. The second signal access region B10 may include at least one bonding pin region 43. In this example, one bonding pin region 43 is illustrated as an example. In some other examples, the second signal access region B10 may include a plurality of bonding pin regions 43 sequentially arranged along the first direction X. Each of the bonding pin regions 43 may include a plurality of bonding pins that may be configured to bond to at least one corresponding circuit board (e.g., a Flexible Printed Circuit (FPC)).

As OLED display technologies continue to mature, OLED display products have demonstrated tremendous market potential. Their excellent display performance offers a wide range of application prospects. Additionally, as the technologies advance and display products become increasingly sophisticated, the specifications for these products are also steadily raised. A lower bezel of the OLED display substrate is reduced, so that the OLED display product can obtain more battery capacity space after the lower bezel is bent, thereby improving a battery life of the display product and improving performance of the display product. In the process of reducing the lower bezel of the display substrate, a processing process of the driver chip is also constantly improving, a dimension of bonding pins of the driver chip is gradually reducing, and a dimension of the driver chip itself is also constantly reducing. As reducing the lower bezel of the display substrate, reduction in the dimension of the driver chip puts forward higher requirements on reliability of the driver chip. When the driver chip is bonded to the lower bezel of the display substrate, the display substrate is affected by a bonding stress in a bonding region of the driver chip, which is prone to deformation. Severe deformation leads to cracks or peeling a local film of the driver chip, thus affecting reliability and stability of the display product.

In an embodiment, a display substrate is provided, which includes a base substrate, a plurality of sub-pixels, a plurality of data lines, a plurality of first contact pads, a plurality of second contact pads, and an inorganic film that is disposed on the base substrate. The base substrate includes a display region and a peripheral region surrounding the display region, the peripheral region includes at least one driver chip disposing region. The plurality of sub-pixels are located in the display region. The plurality of data lines are located in the display region and the peripheral region, and the plurality of sub-pixels and the plurality of data lines are electrically connected. The plurality of first contact pads are located in the at least one driver chip disposing region, and are connected with the plurality of data lines. The plurality of second contact pads are located in the at least one driver chip disposing region, and are located on a side of the plurality of first contact pads away from the display region. The plurality of first contact pads and the plurality of second contact pads are configured to bond to the driver chip. The inorganic film includes at least one inorganic groove. The at least one inorganic groove is located on at least one side of the plurality of first contact pads or the plurality of second contact pads.

According to the display substrate in this embodiment, by providing the inorganic groove in the inorganic film, and the inorganic groove that is located on at least on one side of the plurality of first contact pads or the plurality of second contact pads in the driver chip disposing region, a risk of panel cracks generated after the driver chip is bonded to the display substrate can be reduced, and performance such as reliability and stability of the display substrate can be improved.

In some exemplary implementations, the at least one inorganic groove may include a first inorganic groove, and an orthographic projection of the first inorganic groove on the base substrate may at least partially surround orthographic projections of the plurality of first contact pads or the plurality of second contact pads on the base substrate. For example, the orthographic projection of the first inorganic groove on the base substrate may surround the orthographic projections of the plurality of first contact pads and the plurality of second contact pads on the base substrate. In this example, the inorganic film of the driver chip disposing region can be thinned as a whole, and the first inorganic groove can be formed in entire driver chip disposing region, so that the elastic deformation of the inorganic film and the film breakage difference between the contact pads can be reduced, thereby reducing a risk of inorganic film breakage when the driver chip is bonded.

In some exemplary implementations, an edge of the first inorganic groove may be serrated. In this example, by setting the edge of the first inorganic groove as a non-smooth edge, an etching slope angle of a boundary of the inorganic film can be reduced, and a risk of metal remain caused by the first inorganic groove at an edge of the driver chip disposing region can be reduced.

In some exemplary implementations, the at least one driver chip disposing region may further include a plurality of signal leads. The at least one inorganic groove may include a plurality of second inorganic grooves. At least part of the plurality of second inorganic grooves may be located in the at least one driver chip disposing region, and orthographic projections of the plurality of second inorganic grooves on the base substrate may be not overlapped with orthographic projections of the plurality of first contact pads, the plurality of second contact pads, and the plurality of signal leads on the base substrate. In this example, by forming the plurality of second inorganic grooves in the driver chip disposing region, a bonding pressure can be buffered during a driver chip bonding process, thereby reducing a risk of cracking in the driver chip disposing region.

In some exemplary implementations, the at least one inorganic groove may include at least one third inorganic groove. The at least one third inorganic groove may at least partially surround the plurality of first contact pads and the plurality of second contact pads, and the at least one third inorganic groove may be an annular groove. In this example, by providing the third inorganic groove at least partially surrounding the plurality of first contact pads and the plurality of second contact pads, the third inorganic groove acts as a crack blocking dam, which can prevent the bonding stress from extending outward during the driver chip bonding process, for example, blocking the stress extending outside the driver chip disposing region, thereby reducing a risk of wire breakage around the driver chip disposing region, and improving the reliability and stability of the display substrate.

A solution in this embodiment will be described below through some examples.

FIG. 5 is a schematic diagram of a part of a first signal access region of a display substrate according to at least one embodiment of the present disclosure. FIG. 5 may be a partially enlarged schematic diagram of a region SS1 in FIG. 4. In this example, a left edge region of the driver chip disposing region is described as an example, and a structure of a right edge region of the driver chip disposing region is similar to a structure of the left edge region, which is not be repeated here. The driver chip disposing region in this example may be an region corresponding to an orthographic projection range of the driver chip on the base substrate after the driver chip is bonded to the display substrate.

In some examples, as shown in FIG. 5, the driver chip disposing region 42 may at least include a plurality of contact pads and a plurality of signal leads. The plurality of contact pads of the driver chip disposing region 42 may include a plurality of first contact pads 311, a plurality of second contact pads 312, a plurality of third contact pads 313, and a plurality of dummy contact pads (dummy pumps) 314. The plurality of signal leads of the driver chip disposing region 42 may include a plurality of first signal leads 321, a plurality of second signal leads 322, and a plurality of third signal leads 323.

In some examples, as shown in FIG. 5, the plurality of first contact pads may include a plurality of groups of first contact pads (e.g., three groups of first contact pads). The plurality of groups of first contact pads may be arranged along a second direction Y, and a plurality of first contact pads in each group of first contact pads may be arranged along a first direction X. A plurality of first contact pads 311 may be configured to electrically connect with the driver chip and transmit signals received from the driver chip. For example, a plurality of first contact pads 311 may also be referred to as signal output contact pads. A plurality of first contact pads 311 close to the edge of the display substrate along the first direction X may be electrically connected with a plurality of first signal output lines 331. A plurality of first contact pads 311 located in a middle region of a group of first contact pads along the first direction X may be electrically connected with a plurality of third signal output lines 333. The first signal output lines 331 and the third signal output lines 333 may extend to a side of the driver chip disposing region 42 close to a display region AA. For example, the first signal output line 331 may be configured to transmit a GOA signal, and the third signal output line 333 may be configured to transmit a data signal. In some examples, the first signal output lines 331 and the third signal output lines 333 may be located in a first gate metal layer.

In some examples, at least one first contact pad 311 may include at least two conductive blocks (e.g., two or three conductive blocks) that are electrically connected. For example, the two conductive blocks of the first contact pad 311 may be located in the first gate metal layer and the first source-drain metal layer, respectively, or may be located in a second gate metal layer and a first source-drain metal layer. A first signal output line 331 located in the first gate metal layer and a conductive block, located in a first gate metal layer, of a connected first contact pad 311 may be in an integral structure. A third signal output line 333 located in the first gate metal layer and a conductive block, located in a first gate metal layer, of a connected first contact pad 311 may be in an integral structure. However, the present embodiment is not limited thereto. In some other examples, the at least one first contact pad may include three conductive blocks which are stacked (e.g., the three conductive blocks may be located in the first gate metal layer, the first source-drain metal layer, and the second source-drain metal layer, respectively, or may be located in the second gate metal layer, the first source-drain metal layer, and the second source-drain metal layer, respectively). In some examples, a plurality of conductive blocks of a first contact pad within a group of first contact pads and a plurality of conductive blocks of a first contact pad within an adjacent group of first contact pads may be located in different films. For example, two stacked conductive blocks of a first contact pad within a group of first contact pads may be located in the first gate metal layer and the first source-drain metal layer, and two stacked conductive blocks of the first contact pad within the adjacent group of first contact pads may be located in the second gate metal layer and the first source-drain metal layer. In some other examples, a plurality of conductive blocks of adjacent first contact pads within a group of first contact pads may be located in different films. For example, two stacked conductive blocks of a first contact pad within a group of first contact pads may be located in the first gate metal layer and the first source-drain metal layer, and two stacked conductive blocks of a first contact pad adjacent to the first contact pad within the group of first contact pads may be located in a second gate metal layer and the first source-drain metal layer. In this example, by providing the first contact pad formed by a plurality of stacked conductive blocks, resistance of the first contact pad can be reduced, which is advantageous in providing signal transmission effectiveness.

In some examples, as shown in FIG. 5, a plurality of second contact pads 312 may be arranged in a row along the first direction X to form a group of second contact pads. A plurality of second contact pads 312 may be configured to electrically connect with the driver chip and transmit a signal to the driver chip. The plurality of second contact pads 312 may also be electrically connected with a plurality of pin connection lines 334. The plurality of second contact pads 312 may be electrically connected to a plurality of bonding pins within a corresponding bonding pin region through the plurality of pin connection lines 334. The plurality of second contact pads 312 may also be referred to as signal input contact pads. For example, the driver chip may receive signals transmitted by a circuit board through the bonding pin region through the plurality of second contact pads 312 and the plurality of pin connection lines 334. In some examples, the pin connection line 334 may be located on a side of the second contact pad 312 away from the base substrate. For example, the pin connection line 334 may be located in the second source-drain metal layer. In some other examples, the plurality of second contact pads 312 may include a plurality of groups of second contact pads. The present embodiment is not limited thereto.

In some examples, the at least one second contact pad 312 may include at least one conductive block (e.g., one or two conductive blocks). For example, the two conductive blocks of the second contact pad 312 may be located in the first source-drain metal layer and the second source-drain metal layer, respectively, or the conductive blocks of the second contact pad 312 may be located only in the first source-drain metal layer), wherein the two conductive blocks of the second contact pad 312 may be in direct contact. For example, the conductive block of the second contact pad 312 located in the first source-drain metal layer may be electrically connected with a corresponding pin connection line 334. However, the present embodiment is not limited thereto. In some other examples, the at least one second contact pad 312 may include three stacked conductive blocks (for example, the three conductive blocks may be located in a first gate metal layer, a first source-drain metal layer, and a second source-drain metal layer, or may be located in a second gate metal layer, a first source-drain metal layer, and a second source-drain metal layer, respectively), wherein the conductive blocks located in the second source-drain metal layer and an electrically connected pin connection line may be integrated. In this example, by providing the second contact pad formed by a plurality of stacked conductive blocks, the resistance of the second contact pad can be reduced, which is advantageous in providing signal transmission effectiveness.

In some examples, as shown in FIG. 5, a plurality of third contact pads 313 may be arranged in a row along the first direction X to form a group of third contact pads. The group of third contact pads 313 may be located between a plurality of first contact pads 311 and a plurality of second contact pads 312 in the second direction Y. For example, the group of third contact pads 313 may be located between three groups of first contact pads and one group of second contact pads. An area of a single third contact pad 313 may, for example, be larger or smaller than areas of a single first contact pad 311 and a single second contact pad 312, and the area of the single first contact pad 311 may, for example, be smaller than the area of the single second contact pad 312. The third contact pad 313 may be configured to transmit test and detection signals before the driver chip is unbonded. In some examples, a plurality of third contact pads 313 may be located in the first source-drain metal layer. However, the present embodiment is not limited thereto.

In some examples, as shown in FIG. 5, a plurality of dummy contact pads 314 may be arranged in a row along the second direction Y to form a group of dummy contact pads. The group of dummy contact pads 314 may be located between a plurality of groups of first contact pads 311 and a group of second contact pads 312, and may be located on a side of a group of third contact pads 313 along the first direction X. The at least one dummy contact pad 314 may include at least two stacked dummy conductive blocks (e.g., two or three dummy conductive blocks). For example, the two dummy conductive blocks of the dummy contact pad 314 may be located in the first gate metal layer and the first source-drain metal layer, respectively, or may be located in the second gate metal layer and the first source-drain metal layer, respectively, and the two dummy conductive blocks may be in direct contact. However, the present embodiment is not limited thereto. In some other examples, the at least one dummy contact pad may include three dummy conductive blocks which are stacked (e.g., the three dummy conductive blocks may be located on the first gate metal layer, the first source-drain metal layer, and the second source-drain metal layer, respectively, or may be located in the second gate metal layer, the first source-drain metal layer, and the second source-drain metal layer, respectively). A film structure of the dummy contact pad may be substantially the same as film structures of the first contact pad and the second contact pad, so that a manufacturing process may be simplified, and the dummy contact pad can be synchronously manufactured in a process of manufacturing the first contact pad and the second contact pad.

In some examples, as shown in FIG. 5, a group of first contact pads closest to the display region may be a first group of first contact pads, and a second group of first contact pads and a third group of first contact pads may be sequentially defined along a direction away from the display region. In the first direction X, first alignment marks 341 may be provided on opposite sides of the first group of first contact pads 311. Orthographic projections of the first alignment marks 341 on the base substrate may be cross-shaped. Second alignment marks 342 may be provided on opposite sides of the second group of first contact pads 311. The second alignment marks 342 may be aligned with the first alignment marks 341 along the second direction Y. That is, the second alignment marks 342 are located on a side of the first alignment marks 341 away from the display region. Orthographic projections of the second alignment marks 342 on the base substrate may be inverted L-shaped. The first alignment marks 341 and the second alignment marks 342 may be located in the first gate metal layer, for example. In the first direction X, opposite sides of a group of third contact pads 313 may be provided with third alignment marks 343. Orthographic projections of the alignment marks 343 on the base substrate may be cross-shaped. The third alignment marks 343 may be located in the first source-drain metal layer. In the first direction X, a fourth alignment mark 344 may be provided on a side of the first alignment marks 341 away from the first group of first contact pads 311. The fourth alignment mark 344 and the first alignment mark 341 may be aligned in the first direction X. An orthographic projection of the fourth alignment mark 344 on the base substrate may be an inverted and flipped L-shape. The fourth alignment mark 344 may be located in the first gate metal layer, for example. In this example, a boundary line of the driver chip disposing region 42 parallel to the second direction Y may be located between the first alignment marks 341 and the fourth alignment mark 344. The present embodiment is not limited thereto.

In some examples, as shown in FIG. 5, a plurality of first signal leads 321 of the driver chip disposing region 42 may be located between a plurality of groups of first contact pads 311 and a group of third contact pads 313. The plurality of first signal leads 321 may be configured to transmit signals in the test phase. At least one first signal lead of the plurality of first signal leads 321 may be configured to be electrically connected with a plurality of first contact pads 311 and a plurality of third contact pads 313, and at least one first signal lead may be configured to electrically connect to a plurality of third contact pads 313 and a second signal output line 332. A part of the first signal leads 321 may achieve signal transmission between the first signal output lines 331 and the third contact pads 313, and the other part of the first signal leads 321 may achieve signal transmission between the second signal output line 332 and the third contact pads 313. The first signal output line 331 and the second signal output line 332 may be configured to transmit a control signal (including, for example, a GOA signal). The second signal output line 332 may extend, for example, in the first direction X, and may be electrically connected with the first connection line 351. A first signal leads 321 electrically connected with a plurality of second signal output lines 332 may be interspersed and arranged between a plurality of dummy contact pads 314 along the second direction Y. For example, a plurality of first signal leads 321 and a plurality of dummy contact pads 314 may be arranged at intervals along the second direction Y. In some examples, a plurality of first signal leads 321 may be located in the first gate metal layer, and a plurality of first connection lines 351 may be located in the second gate metal layer. However, the present embodiment is not limited thereto.

In some examples, as shown in FIG. 5, a plurality of second signal leads 322 of the driver chip disposing region 42 may be located between a group of third contact pads 313 and a group of second contact pads 312. The plurality of second signal leads 322 may be electrically connected with a plurality of third contact pads 313 and a plurality of second connection lines 352. For example, the second signal leads 322 may extend along the first direction X. The second connection lines 352 may extend, for example, along the second direction Y. The second signal lead 322 may be configured to transmit the signals in the test phase. In some examples, the second signal lead 322 may be located in the first gate metal layer. The second connection lines 352 may be located, for example, in the first source-drain metal layer. However, the present embodiment is not limited thereto.

In some examples, as shown in FIG. 5, the plurality of third signal leads 323 of the driver chip disposing region 42 may be located between a plurality of groups of first contact pads 311 and one group of third contact pads 313. The plurality of third signal leads 323 may be located on a side of the plurality of first signal leads 321 away from one group of dummy contact pads 314 in the first direction X. The plurality of third signal leads 323 may be electrically connected with the plurality of first contact pads 311 and the plurality of third contact pads 313. The plurality of third signal leads 323 may be electrically connected with the plurality of third output signal lines 333 through the plurality of first contact pads 311. The third output signal lines 333 and the third signal leads 313 may be located in the first gate metal layer. The third signal leads 313 may be configured to transmit a data signal in the test phase.

In some examples, as the process capability for the driver chip is improved, a dimension of the driver chip decreases, dimensions of the contact pad and the dummy contact pad in the driver chip disposing region 42 decrease, the wiring space also decreases, a spacing between the first contact pad 311 and the second contact pad 312 decreases, and a quantity of dummy contact pads decreases (for example, the dummy contact pads arranged between the plurality of first signal leads and the plurality of third signal leads along the first direction X are no longer provided). As the dimension of the driver chip decreases, when the driver chip is bonded to the display substrate, the driver chip disposing region is deformed by a bonding pressure, and when the dimension and the quantity of dummy contact pads serving as supporting functions decrease, the risk of cracks existing in the driver chip disposing region increases, which affects the reliability and stability of the display substrate. In this embodiment, by optimizing the design of the inorganic film in the first signal access region, the risk of cracks in the driver chip disposing region during the driver chip bonding process can be reduced.

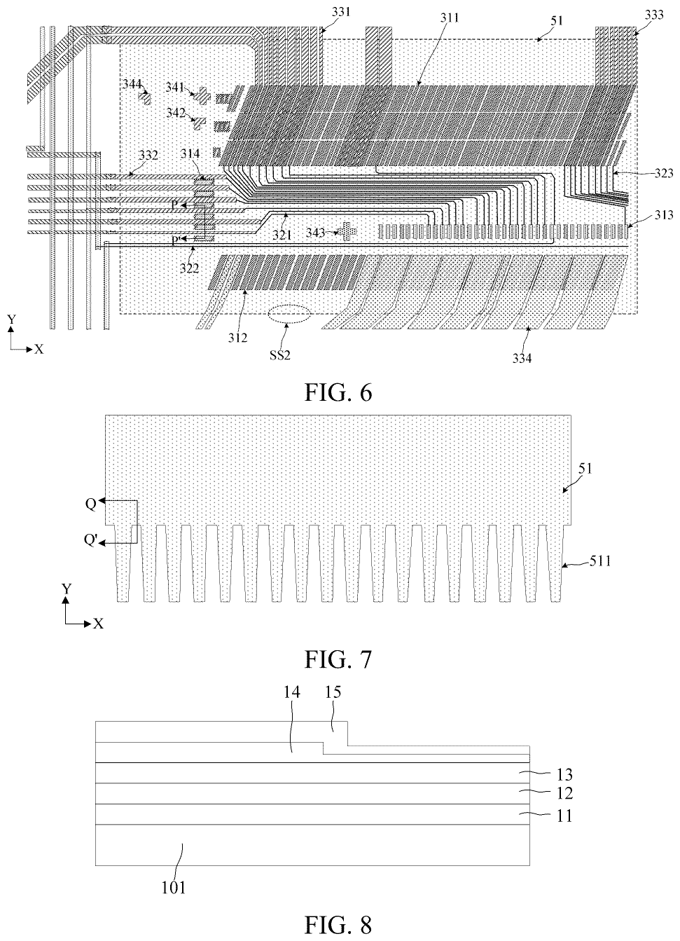

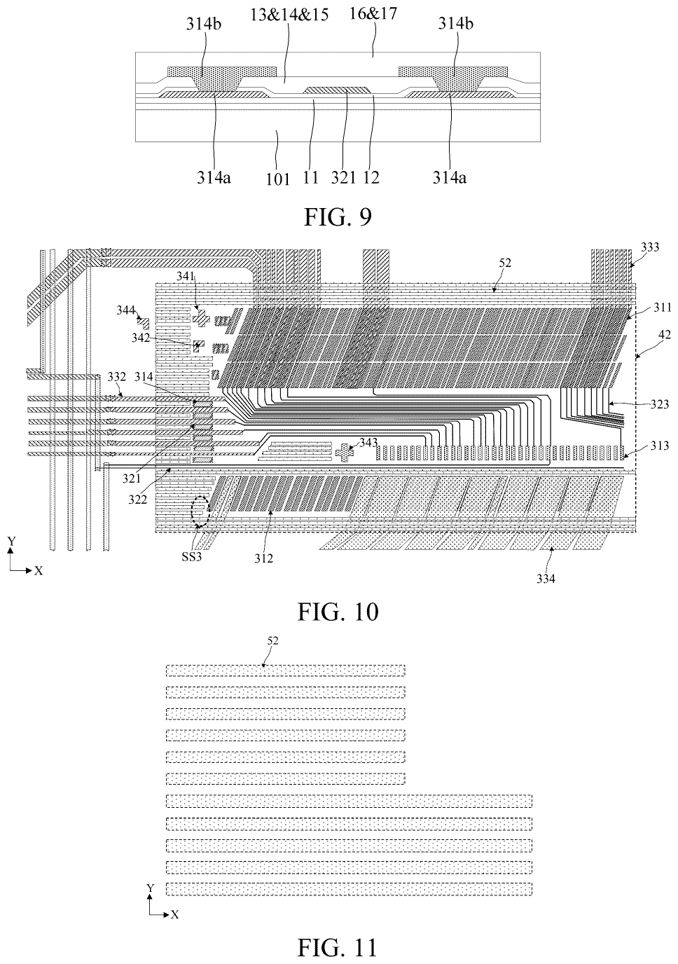

FIG. 6 is a schematic diagram of a part of a first signal access region of a display substrate according to at least one embodiment of the present disclosure. FIG. 7 is a partially enlarged view of a region SS2 in FIG. 6. FIG. 8 illustrates schematically a cross-sectional view of a part taken along a direction Q-Q′ in FIG. 7. FIG. 9 is a cross-sectional view of a part taken along a direction P-P′ in FIG. 6.

In some examples, as shown in FIGS. 6 to 9, the driver chip disposing region may include a base substrate 101 and a first insulation layer 11, a first gate metal layer, a second insulation layer 12, a second gate metal layer, a third insulation layer 13, a fourth insulation layer 14, a fifth insulation layer 15, a first source-drain metal layer, a sixth insulation layer 16, a second source-drain metal layer, and a seventh insulation layer 17 disposed on the base substrate 101. A first signal lead 321, a second signal lead 322, and a third signal lead 323 may be located in the first gate metal layer or the second gate metal layer, and a pin connection line 334 may be located in the second source-drain metal layer. A plurality of third contact pads 313 may be located in the first source-drain metal layer, a plurality of first contact pads 311 and a plurality of second contact pads 312 may each include two layers of stacked conductive blocks (for example, the two layers of conductive blocks may be located in the first gate metal layer and the first source-drain metal layer, respectively), and the dummy contact pad 314 may include two layers of stacked dummy conductive blocks.

In some examples, as shown in FIG. 9, at least one dummy contact pad 314 may include a first dummy conductive block 314a and a second dummy conductive block 314b which are stacked, wherein the first dummy conductive block 314a may be located in the first gate metal layer, and the second dummy conductive block 314b may be located in the first source-drain metal layer. The second dummy conductive block 314b may be in contact with the first dummy conductive block 314a. A first signal line 321 between adjacent dummy contact pads 314 may be located, for example, in the second gate metal layer. Film structures of the first contact pad and the second contact pad may be similar to a film structure of the dummy contact pad, which is not be repeated here. A sixth insulation layer and a seventh insulation layer on a side of the first contact pad and the second contact pad away from the base substrate may be removed to expose at least a part of surfaces of the first contact pad and the second contact pad to achieve subsequent bonding connection with the driver chip.

In some examples, an inorganic film of the first signal access region may include, for example, a first insulation layer 11, a second insulation layer 12, a third insulation layer 13, a fourth insulation layer 14, and a fifth insulation layer 15. An inorganic film of the first signal access region may include, for example, a first inorganic groove 51. An orthographic projection of the first inorganic groove 51 on the base substrate may at least partially surround orthographic projections of a plurality of first contact pads 311 or a plurality of second contact pads 312 on the base substrate. As shown in FIG. 6, the orthographic projection of the first inorganic groove 51 on the base substrate may surround the orthographic projections of the plurality of first contact pads 311 and the plurality of second contact pads 312 on the base substrate. A periphery of each first contact pad 311 may be surrounded by a continuous first inorganic groove, and a periphery of each second contact pad 312 may be surrounded by a continuous first inorganic groove. However, the present embodiment is not limited thereto. In some other examples, at least one side of the at least one first contact pad may be not surrounded by the first inorganic groove. As another example, the first inorganic groove disposed around the at least one first contact pad may be discontinuous.

In some examples, as shown in FIGS. 6 to 9, the first inorganic groove 51 may be formed in the first signal access region by thinning the fourth insulation layer 14 and the fifth insulation layer 15. The first signal access area includes a driver chip disposing region and a region other than the driver chip disposing region (hereinafter simply referred to as a remaining region). A thickness of the fourth insulation layer 14 and the fifth insulation layer 15 in the driver chip disposing region may be less than a thickness of the fourth insulation layer 14 and the fifth insulation layer 15 in the remaining region, so that a total thickness of the inorganic film of the driver chip disposing region is less than a total thickness of the inorganic film in the remaining region, thereby forming the first inorganic groove in the driver chip disposing region. When the thickness of the inorganic film in the driver chip installation region is large, the inorganic film is easily subjected to the bonding pressure when the driver chip is bonded and installed, and the risk of cracking is increased due to elastic deformation. As shown in FIG. 8, in a region where no contact pad is provided in the driver chip disposing region, by reducing the total thickness of the inorganic film in the driver chip disposing region, the elastic deformation of the inorganic film can be reduced accordingly, thereby reducing a risk of inorganic film breakage. As shown in FIG. 9, in a region where a contact pad is provided in the driver chip disposing region, by reducing the total thickness of the inorganic film, film breakage differences between the contact pads, and between the contact pad and the signal lead can be reduced, and a risk of inorganic film breakage between the contact pads, and between the contact pads and the signal leads can be reduced when the driver chip is bonded.

In this example, the inorganic film of the driver chip disposing region is thinned as a whole, and the first inorganic groove can be formed in the driver chip disposing region, so that the elastic deformation of the inorganic film and the film breakage difference between the contact pads, and between the contact pads and the signal leads can be reduced, thereby reducing a risk of the inorganic film breakage when the driver chip is bonded.

In some other examples, the first inorganic groove 51 may be formed in the first signal access region by thinning at least one of the first insulation layer 11 to the fifth insulation layer 15. For example, the first inorganic groove 51 may be formed by thinning the third insulation layer 13 to the fifth insulation layer 15, or the first inorganic groove 51 may be formed by thinning the first insulation layer 11 to the fifth insulation layer 15. However, the present embodiment is not limited thereto. In some other examples, the driver chip disposing region may be not provided with the third gate metal layer, and the first inorganic groove may be formed by removing the fourth insulation layer or the fifth insulation layer of the driver chip disposing region.

In some examples, as shown in FIG. 7, an edge of the first inorganic groove 51 may be serrated. The edge of the first inorganic groove 51 may have a plurality of serrated portions 511 arranged at intervals. An orthographic projection of the serrated portion 511 on the base substrate may be trapezoidal. In some other examples, the orthographic projection of the serration on the base substrate may be rectangular, triangular, or semicircular. In this example, by setting the edge of the first inorganic groove as a non-smooth edge, an etching slope angle of a boundary of the inorganic film can be reduced, and a risk of metal remain caused by the first inorganic groove at an edge of the driver chip disposing region can be reduced.

FIG. 10 is another schematic diagram of a part of a first signal access region of a display substrate according to at least one embodiment of the present disclosure. FIG. 11 is a partially enlarged schematic diagram of a region SS3 in FIG. 10.

In some examples, as shown in FIGS. 10 and 11, the inorganic film of the driver chip disposing region 42 may include a plurality of second inorganic grooves 52. The plurality of second inorganic grooves 52 may be strip grooves in a same extending direction. For example, all of the plurality of second inorganic grooves 52 may extend in the first direction X, or the extending direction of the plurality of second inorganic grooves 52 may intersect with the first direction X. However, the present embodiment is not limited thereto. For example, the plurality of second inorganic grooves 52 may extend along the second direction Y. In some other examples, at least a part of the plurality of second inorganic grooves may extend in different directions. For example, extending directions of a part of the second inorganic grooves may intersect with each other. The second inorganic grooves whose extending directions intersect with each other may or may not communicate with each other. The present embodiment is not limited thereto.

In some examples, as shown in FIG. 10, the plurality of second inorganic grooves 52 may be located at least in the driver chip disposing region 42 and may be not overlapped with orthographic projections of a plurality of contact pads (including, for example, a plurality of first contact pads 311, a plurality of second contact pads 312, a plurality of third contact pads 313, and a plurality of dummy contact pads 314), a plurality of signal leads (including, for example, a plurality of first signal leads 321, a plurality of second signal leads 322, and a plurality of third signal leads 323), and a plurality of alignment marks (including, for example, first alignment marks 341, second alignment marks 342, and third alignment marks 343) within the driver chip disposing region 42 on the base substrate. In other words, the plurality of second inorganic grooves 52 may be not overlapped with an orthographic projection of a metal film within the driver chip disposing region 42 on the base substrate. The plurality of second inorganic grooves 52 may be disposed in a region where no wires or contact pads are located in the driver chip disposing region 42. For example, the plurality of second inorganic grooves 52 may be disposed on a side of the plurality of first contact pads 311 close to the display region, may be disposed on a side of the first alignment mark 341 and the second alignment mark 342 close to the fourth alignment mark 344, may be disposed in a spacing region of adjacent first signal leads 321 and on a side of the dummy contact pads 314 away from the third contact pads 313, may be disposed in a peripheral region of a group of second contact pads 312 along the first direction X, may be disposed on a side of the group of second contact pads 312 away from the display region, or may be disposed in an empty region on a side of the third alignment mark 343 away from a group of third contact pads 313.

In some examples, as shown in FIGS. 10 and 11, lengths of the plurality of second inorganic grooves 52 along the first direction X may be different, and may be determined according to an empty range of a region in which the plurality of second inorganic grooves 52 are located. Lengths (i.e. widths) of the plurality of second inorganic grooves 52 along the second direction Y may be substantially the same, and spacings between adjacent second inorganic grooves 52 may be substantially the same. In some examples, widths of the second inorganic grooves 52 and the spacings between adjacent second inorganic grooves 52 may be substantially the same. For example, depths of the second inorganic groove 52 may be about 4000 Angstroms to 8000 Angstroms, the widths of the second inorganic groove 52 may be about 6 micrometers to 8 micrometers, and the spacings between adjacent second inorganic grooves 52 may be about 6 micrometers to 8 micrometers. However, the present embodiment is not limited thereto. A dimension of the second inorganic groove in this example buffers the bonding pressure, thereby reducing a risk of cracking in the driver chip disposing region.

According to the display substrate provided in this example, by optimizing the design of the inorganic film in the driver chip disposing region to form the plurality of second inorganic grooves, the bonding pressure can be buffered during the driver chip bonding process, thereby reducing the risk of cracking in the driver chip disposing region.

In this example, a method for forming the second inorganic groove may refer to a method for forming the first inorganic groove. For example, the second inorganic groove may be formed by thinning at least one of the first insulation layer to the fifth insulation layer or removing at least one of the first insulation layer to the fifth insulation layer, which is not be repeated here. Remaining description of the display substrate in this embodiment, reference may be made to the description of the aforementioned embodiments, which is not repeated here.

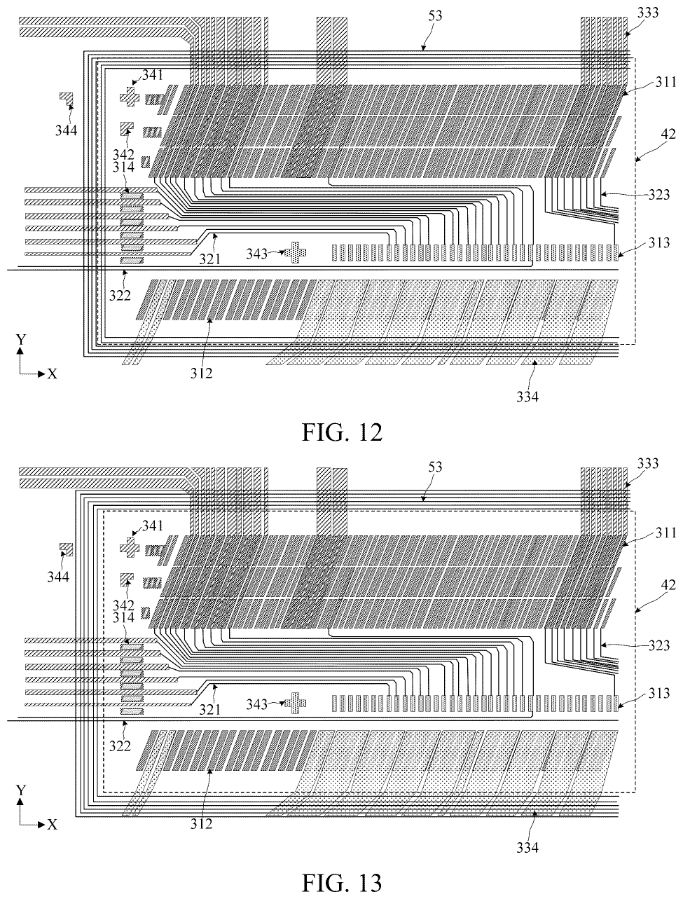

FIG. 12 is another schematic diagram of a part of a first signal access region of a display substrate according to at least one embodiment of the present disclosure. In some examples, as shown in FIG. 12, an inorganic film of a first signal access region may include a plurality of third inorganic grooves 53. The plurality of third inorganic grooves 53 may be annular grooves. At least one third inorganic groove 53 may surround a plurality of first contact pads 311 and a plurality of second contact pads 312. For example, the third inorganic groove 53 may be disposed at a periphery of the plurality of first contact pads 311 and the plurality of second contact pads 312 to enclose the plurality of first contact pads 311 and the plurality of second contact pads 312. An orthographic projection of the at least one third inorganic groove 53 on the base substrate may be not overlapped with orthographic projections of the plurality of first contact pads 311 and the plurality of second contact pads 312 on the base substrate. In some other examples, at least one third inorganic groove may partially surround a plurality of first contact pads 311 and a plurality of second contact pads 312.

In some examples, the at least one third inorganic groove 53 may be an integrally communicating annular groove. For example, the third inorganic groove 53 may be formed around a driver chip disposing region 42. Alternatively, the at least one third inorganic groove 53 may include a plurality of groove segments arranged at intervals, and the plurality of groove segments may be arranged at intervals to form an annular shape, for example, they may form non-communicating annular grooves arranged around an edge of the driver chip disposing region. For example, when the annular groove includes a plurality of non-communicating groove segments, lengths of the plurality of groove segments may be substantially the same or at least partially different, widths of the plurality of groove segments may be substantially the same or at least partially different, and spacings between adjacent groove segments may be substantially the same. The present embodiment is not limited thereto.

In some examples, widths of a plurality of third inorganic grooves 53 may be substantially the same, and spacings between adjacent third inorganic grooves 53 may be substantially the same. For example, the widths of the third inorganic grooves 53 and the spacings between the adjacent third inorganic grooves 53 may be substantially the same. For example, depths of the third inorganic groove 53 may be about 4000 Angstroms to 8000 Angstroms, the widths of the third inorganic groove 53 may be about 6 micrometers to 8 micrometers, and the spacings between adjacent third inorganic grooves 53 may be about 6 micrometers to 8 micrometers. The present embodiment is not limited thereto. A dimension of the third inorganic groove in this example is advantageous in acting as a crack blocking dam, and the bonding stress can be prevented from extending outward during a bonding process of a driver chip.

In some examples, at least one third inorganic groove 53 may be located inside the edge of the driver chip disposing region 42, and at least one third inorganic groove 53 may be located outside the edge of the driver chip disposing region 42. A method for forming the third inorganic groove in this example may refer to a method for forming the second inorganic groove. For example, the third inorganic groove may be formed by thinning at least one of the first insulation layer to the fifth insulation layer or removing at least one of the first insulation layer to the fifth insulation layer, which is not be repeated here.

Remaining description of the display substrate in this embodiment may be referred to the description in the aforementioned embodiments, which is not repeated here.

In this example, by providing the plurality of third inorganic grooves surrounding the driver chip disposing region 42, the third inorganic groove acts as a crack blocking dam, which can prevent the bonding stress from extending outward during the driver chip bonding process, for example, blocking the stress extending outside the driver chip disposing region, thereby reducing a risk of wire breakage around the driver chip disposing region, and improving the reliability and stability of the display substrate.

FIG. 13 is another schematic diagram of a part of a first signal access region of a display substrate according to at least one embodiment of the present disclosure. In some examples, as shown in FIG. 13, an inorganic film of a first signal access region may include a plurality of third inorganic grooves 53. The plurality of third inorganic grooves 53 may be annular grooves surrounding a driver chip disposing region 42. All of the plurality of third inorganic grooves 53 may be located outside an edge of the driver chip disposing region 42.

Remaining description of the display substrate in this embodiment may be referred to the description in the aforementioned embodiments, which is not repeated here.

In this example, by providing the third inorganic grooves surrounding outside the edge of the driver chip disposing region 42, the bonding stress can be prevented from extending outward during a bonding process of the driver chip, and a risk of wire breakage around the driver chip disposing region can be reduced, and reliability and stability of the display substrate can be improved.

In some other examples, the inorganic film of the first signal access region may be provided with a first inorganic groove, a second inorganic groove. Alternatively, the inorganic film of the first signal access region may be provided with a first inorganic groove, a second inorganic groove, and a third inorganic groove. Alternatively, the inorganic film of the first signal access region may be provided with the first inorganic groove and the third inorganic groove. The present embodiment is not limited thereto.

A display apparatus is further provided in at least an embodiment of the present disclosure, which includes the display substrate as described above. In some examples, the display apparatus may be any product or component with a display function, such as a mobile phone, a tablet computer, a television, a display, a laptop computer, a digital photo frame, and a navigator.

The drawings of the present disclosure only involve structures involved in the present disclosure, and other structures may refer to conventional designs. The embodiments of the present disclosure, i.e., features in the embodiments, may be combined with each other to obtain new embodiments if there is no conflict. Those of ordinary skills in the art should understand that modifications or equivalent replacements may be made to the technical solutions of the present disclosure without departing from the essence and scope of the technical solutions of the present disclosure, which shall all fall in the scope of the claims of the present application.

1. A display substrate, comprising:
a base substrate comprising a display region and a peripheral region surrounding the display region, wherein the peripheral region comprises at least one driver chip disposing region;
a plurality of sub-pixels located in the display region;
a plurality of data lines located in the display region and the peripheral region, and the plurality of sub-pixels and the plurality of data lines being electrically connected;
a plurality of first contact pads which are located in the at least one driver chip disposing region and are connected with the plurality of data lines;
a plurality of second contact pads which are located in the at least one driver chip disposing region and on a side of the plurality of first contact pads away from the display region, the plurality of first contact pads and the plurality of second contact pads configured to bond to a driver chip; and
an inorganic film comprising at least one inorganic groove located on at least one side of the plurality of first contact pads or the plurality of second contact pads.

2. The display substrate of claim 1, wherein the at least one inorganic groove comprises a first inorganic groove, an orthographic projection of the first inorganic groove on the base substrate at least partially surrounds orthographic projections of the plurality of first contact pads or the plurality of second contact pads on the base substrate.

3. The display substrate of claim 2, wherein the orthographic projection of the first inorganic groove on the base substrate surrounds orthographic projections of the plurality of first contact pads and the plurality of second contact pads on the base substrate.

4. The display substrate of claim 2, wherein an edge of the first inorganic groove is serrated.

5. The display substrate of claim 2, wherein the at least one driver chip disposing region is located in a first signal access region of the peripheral region; a total thickness of the inorganic film in the at least one driver chip disposing region is less than a total thickness of the inorganic film in a region other than the driver chip disposing region in the first signal access region.

6. The display substrate of claim 1, wherein the at least one driver chip disposing region further comprises a plurality of signal leads;
the at least one inorganic groove comprises a plurality of second inorganic grooves, at least part of the plurality of second inorganic grooves is located in the at least one driver chip disposing region, and orthographic projections of the plurality of second inorganic grooves on the base substrate are not overlapped with orthographic projections of the plurality of first contact pads, the plurality of second contact pads, and the plurality of signal leads on the base substrate.

7. The display substrate of claim 6, wherein the plurality of second inorganic grooves extend in a same direction.

8. The display substrate of claim 1, wherein the at least one inorganic groove comprises at least one third inorganic groove at least partially surrounding the plurality of first contact pads and the plurality of second contact pads, the at least one third inorganic groove is an annular groove.

9. The display substrate of claim 8, wherein an orthographic projection of the at least one third inorganic groove on the base substrate is not overlapped with orthographic projections of the plurality of first contact pads and the plurality of second contact pads on the base substrate.

10. The display substrate of claim 1, wherein the plurality of first contact pads comprise a plurality of groups of first contact pads, each group of first contact pads is arranged along a first direction, the plurality of group of first contact pads are arranged along a second direction, the first direction intersects with the second direction;
the plurality of second contact pads comprise at least one group of second contact pads, each group of second contact pads is arranged along the first direction.

11. The display substrate of claim 10, further comprising a plurality of third contact pads located in the at least one driver chip disposing region; wherein the plurality of third contact pads are located between the plurality of first contact pads and the plurality of second contact pads in the second direction;
the plurality of third contact pads comprise at least one group of third contact pads, each group of third contact pads is arranged along the first direction.

12. The display substrate of claim 11, further comprising a plurality of dummy contact pads located in the at least one driver chip disposing region; wherein the plurality of dummy contact pads comprise at least one group of dummy contact pads, each group of dummy contact pads is arranged along the second direction, and each group of dummy contact pads is located on at least one side of the plurality of third contact pads in the first direction.

13. The display substrate of claim 11, further comprising a plurality of signal leads located in the at least one driver chip disposing region; wherein the plurality of signal leads are electrically connected with the plurality of third contact pads, respectively, and are configured to transmit a signal in a test phase.

14. The display substrate of claim 1, wherein in a direction perpendicular to the display substrate, the display region comprises: a base substrate and a circuit structure layer disposed on the base substrate, the circuit structure layer comprises a first semiconductor layer, a first insulation layer, a first gate metal layer, a second insulation layer, a second gate metal layer, a third insulation layer, a second semiconductor layer, a fourth insulation layer, a third gate metal layer, a fifth insulation layer, a first source-drain metal layer, a sixth insulation layer, a second source-drain metal layer and a seventh insulation layer disposed on the base substrate;
the inorganic film comprises a first insulation layer, a second insulation layer, a third insulation layer, a fourth insulation layer, and a fifth insulation layer disposed on the base substrate sequentially; the at least one inorganic groove is configured to be formed by reducing a thickness of at least one of the first insulation layer to the fifth insulation layer.

15. The display substrate of claim 14, wherein at least one contact pad of the plurality of first contact pads and the plurality of second contact pads comprises at least two conductive blocks electrically connected; the at least two conductive blocks are located in at least two metal layers of the first gate metal layer, the second gate metal layer, the third gate metal layer, the first source-drain metal layer, and the second source-drain metal layer.

16. A display apparatus, comprising the display substrate of claim 1.
